(19) United States
(12) Patent Application Publication
(10) Pub. No.: US 2007/0284624 A1
(43) Pub. Date: Dec. 13, 2007

(54) Optical semiconductor device with sensitivity improved

(75) Inventor: Takeshi Iwai, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/802,967

(22) Filed: May 29, 2007

(30) Foreign Application Priority Data
May 29, 2006 (JP) 2006-147642

(51) Int. Cl. H01L 29/76; H01L 29/745

(52) U.S. Cl. 257/213

(57) ABSTRACT

An optical semiconductor device containing a photodiode, includes a first semiconductor layer of a first conductive type; and a channel layer of a second conductive type formed from a surface portion of the first semiconductor layer in a light receiving region. The channel layer and the first semiconductor layer in the light receiving region form a p-n junction region.

### BACKGROUND OF THE INVENTION

1. Field of the Invention

The present invention relates to an optical semiconductor device, and especially relates to an optical semiconductor device in which sensitivity is improved.

2. Description of Related Art

Development of a light receiving element for light of shorter wavelength such as blue laser is advanced in order to realize high density recording in a recording apparatus. On the other hand, when an oscillating central wavelength of a semiconductor laser device used as a light source of light signals is short, an optical-absorption coefficient of semiconductor for receiving the laser light becomes large and an invasive length in the semiconductor becomes short. As a result, it is required to prevent reduction of quantum efficiency according to recombination of photo carriers in the vicinity of surface of the semiconductor in order to take out the photo carriers efficiently.

As a technique aiming to obtain a light receiving element having a high sensitivity and high speed response in response to light of short wavelength, a light receiving element and a manufacturing method thereof and a circuit built-in type light receiving element are disclosed in Japanese Laid Open Patent Publication (JP-P2004-87979A). FIG. 1 is a cross sectional view showing a structure of a circuit built-in type light receiving element in the related art. This circuit built-in type light receiving element 120 has a P-type semiconductor substrate 101 made of silicon, having the resistivity of approximately 40 Ωcm, and a P-type high concentration embedding diffusion layer 102, a P-type high specific resistance epitaxial layer 103 having the resistivity of 100 Ωcm or more, and an N-type epitaxial layer 106 having the resistivity of approximately 1 to 5 Ωcm are laminated in this order on a P-type semiconductor substrate 101. The circuit built-in type light receiving element 120 has a photodiode region and a bipolar element region adjacent thereto. The photodiode region (left side in the figure) and the transistor element region (right side in the figure) are separated by a P-type embedding separating diffusion layer 104 formed in the P-type high resistivity epitaxial layer 103 to reach a boundary with the N-type epitaxial layer 106 from a boundary with P-type high concentration embedding diffusion layer 102 and by a P-type separation diffusion layer 107 formed to reach the P-type embedding separation diffusion layer 104 from a surface of the boundary with the N-type epitaxial layer 106.

An N-type impurities diffusion layer 108 is formed in the photodiode region with diffusion of N-type impurities in depth of equal to or less than 0.3 μm (for example, 0.3 μm) from a surface of the N-type epitaxial layer 106 and at a concentration in which a peak concentration of the impurities is lower than 1×10²⁰ cm⁻³, e.g., about 8×10¹⁹ cm⁻³.

An N-type embedding diffusion layer 105 is formed in the transistor element region to be embedded into the surface of the P-type high resistivity epitaxial layer 103. An N-type well diffusion layer 109 and an N-type impurity diffusion layer 108 as a collector layer are formed on the N-type embedding diffusion layer 105 adjacently each other. A P⁺ based diffusion layer 111 formed to be adjacent with a P-based diffusion layer 110 and with both sides of the P-based diffusion layer 110 is provided in the N-type well diffusion layer 109. An N-type emitter diffusion layer 112 is formed in a region of the P-based diffusion layer 110.

As described above, an insulating film for surface protection is formed all over the surface of the N-type epitaxial layer 106 where each layer in the photodiode region and each layer in the transistor element region are formed respectively. The insulating film for surface protection has openings respectively on the N-type impurities diffusion layer 108 and on the P-type separating diffusion layer 107 in the photodiode region, on the N-type impurities diffusion layer 108 that is a collector pull-up layer of the bipolar transistor region, on the P⁺ based diffusion layer 111, and the N-type emitter diffusion layer 112. A hard-wiring (electrode) metal layer 114 is provided on respective openings.

The photo carriers generated in the N-type impurities diffusion layer 108 are moved to a depletion layer by an internal electric field generated on the basis of concentration gradient of N-type impurities, and thus a photoelectric current flows. However, when concentration of impurities in the N-type impurity diffusion layer 108 is high, a lifetime of photo carriers becomes short and the photo carriers recombine before reaching the depletion layer to disappear. For this reason, the photo carriers cannot contribute to the generation of the photoelectric current, and therefore quantum efficiency of the light receiving element decreases. As described above, when an absorption coefficient of light increases in accordance with shortening the wavelength of light and an invasive length of the light in semiconductor layers becomes short, the photo carriers generated in the N-type impurity diffusion layer 108 increase. As a result, when concentration of impurities in the N-type impurity diffusion layer 108 is high, reduction of a quantum efficiency of the light receiving element is apparently shown. In order to prevent reduction of the quantum efficiency on the basis of recombination of the photo carriers in a high concentration impurities and a diffusion layer, a profile of concentration is optimized.

As a first method for optimizing, the internal electric field is strengthened by shallowly forming the N-type impurity diffusion layer 108 to set a steep diffusion profile when concentration of impurities in the N-type impurity diffusion layer 108 is high. As a result, a moving speed at which the photo carriers move to a depletion layer becomes higher in comparison with a case of deeply forming the N-type impurities diffusion layer 108, therefore it is possible for the photo carriers to be moved into the depletion layer before recombination.

As a second method for optimizing, when the N-type impurity diffusion layer 108 is deeply formed, a lifetime of photo carriers can be prolonged by lowering the concentration of impurities. As a result, it is possible for the photo carriers to move into the depletion layer without recombination.

In each of the first and the second methods mentioned above, it is required for a peak position of an impurity concentration to be set on the surface of a semiconductor or near the surface as possible in order to restraining recombination of carriers in the N-type impurity diffusion layer 108. To realize this, the ion-implantation method through an oxide film is necessarily required. However, a production cost increases because lead time is prolonged in accordance with forming of the oxide film. In addition, since heat treatment at a high temperature to regions other than a light receiving section such as a circuit element is required, it is difficult to precisely control a diffusion layer in the light receiving section. Therefore, a technique is desired, which can manufacture a light receiving element in a simple way and low cost process, and the light receiving element can receive light of short wavelength such as a blue laser in a high sensitivity and in high-speed response.

In conjunction with the above description, a divisional light receiving element, a circuit built-in light receiving element, and an optical disk device are disclosed in Japanese Laid Open Patent Publication (JP-P2003-92424A). The divisional light receiving element includes a plurality of second conductivity type diffusion layers formed on a first conductivity type semiconductor layer while keeping a predetermined interval from each other; a leak prevention layer which is formed at least between a plurality of second conductivity type diffusion layers on the first conductivity type semiconductor layer and which prevents leakage occurring between the second conductivity type diffusion layers; and a dielectric film formed at least in a region to which light enters on the first conductivity type semiconductor layer including the second conductivity type diffusion layers and the leakage prevention layer.

A solid imaging device and a light receiving element are disclosed in Japanese Laid Open Patent Publication (JP-A-Heisei 11-214668). The solid imaging device includes a first conductivity type semiconductor substrate; a plurality of second conductivity type accumulation layers for accumulating signal electric charge by incidence of light, which are formed on the semiconductor substrate; an insulation layer formed on upper sides of the accumulation layers; an optical transparent electrode formed on an upper side of the insulation layer; voltage supplying means for applying electric potential to the optical transparent electrode and for forming a reversal layer on surfaces of the accumulation layers located downward; and signal transmission means for scanning the signal electric charge accumulated in the accumulation layers and for outputting it as image signals to outside.

### SUMMARY

In one embodiment of the present invention, an optical semiconductor device containing a photodiode, includes a first semiconductor layer of a first conductive type; and a channel layer of a second conductive type formed from a surface portion of the first semiconductor layer in a light receiving region. The channel layer and the first semiconductor layer in the light receiving region form a p-n junction region.

In another embodiment of the present invention, an operation method of an optical semiconductor device, the optical semiconductor device is provided which includes a first semiconductor layer of a first conductive type; a second semiconductor layer of a second conductive type formed in a surface portion on the semiconductor layer; a third semiconductor layer of the first conductive type formed under the first semiconductor layer; a fourth semiconductor layer of the first conductive type formed to pass through the first semiconductor layer to the third semiconductor layer; a first electrode provided on the second semiconductor layer; and a second electrode provided on the fourth semiconductor layer. The operation method of the optical semiconductor device is achieved by applying a reverse bias voltage between the first semiconductor layer and the second semiconductor layer to form a channel layer of the second conductive type in a surface portion of the first semiconductor layer; and by detecting a photoelectric current generated when a light is inputted in a light receiving region, in which a pn junction region is formed.

According to the embodiments of the present invention, an optical semiconductor device with a high sensitivity and with high-speed response can be provided as a receiving element for short wavelength such as the blue laser. An optical semiconductor device with the high sensitivity and in high-speed response as the receiving element for short wavelength light, which can be manufactured in a simple way and low cost process can be provided.

### BRIEF DESCRIPTION OF THE DRAWINGS

The above and other objects, advantages and features of the present invention will be more apparent from the following description of embodiments taken in conjunction with the accompanying drawings, in which:

FIG. 1 is a cross sectional view showing a structure of a conventional circuit built-in type light receiving element;

FIG. 2 is a cross sectional view showing a structure of an optical semiconductor device according to an embodiment of the present invention;

FIG. 3 is a plan view showing a structure of an optical semiconductor device according to the embodiment of the present invention;

FIG. 4 is a cross sectional view showing an operation principle of the optical semiconductor device according to the embodiment of the present invention;

FIGS. 5A to 5L are cross sectional views showing a manufacturing method of the optical semiconductor device in the embodiment of the present invention; and

FIG. 6 is a flowchart showing an operation of the optical semiconductor in the embodiment of the present invention.

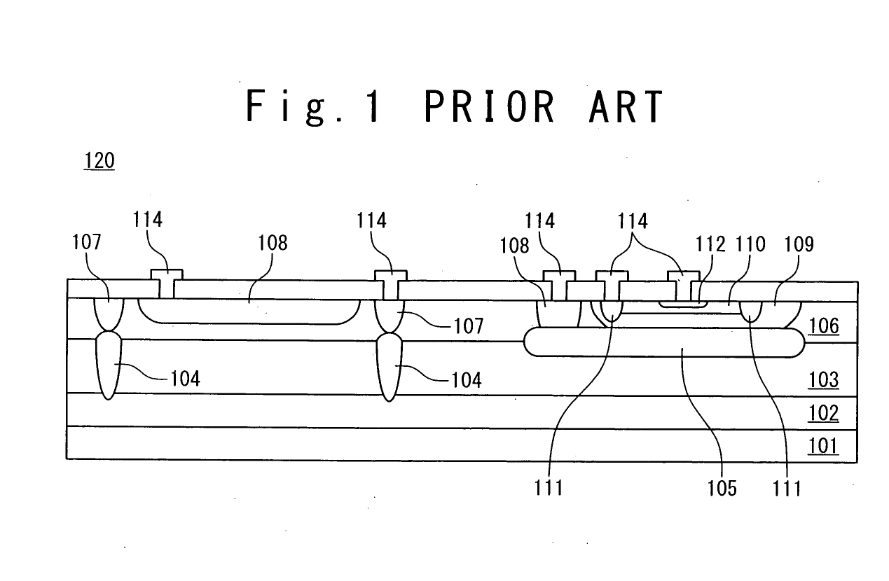

### DESCRIPTION OF THE PREFERRED EMBODIMENTS

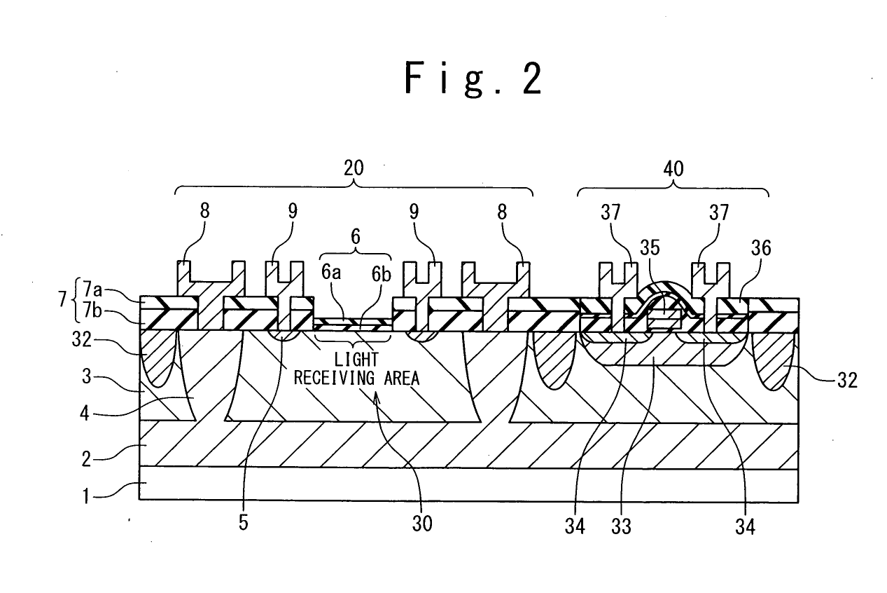

Hereinafter, an optical semiconductor device of the present invention will be described with reference to the attached drawings. FIG. 2 is a cross sectional view showing the optical semiconductor device in which a photodiode and a MOS transistor are formed on a same semiconductor substrate, as an example of a configuration of the optical semiconductor device according to the embodiment of the present invention. Referring to FIG. 2, a photodiode region 20 includes a P-type semiconductor substrate 1, a P⁺ type embedded layer 2, a P-type epitaxial layer 3, a P⁺ type diffusion layer 4, an N⁺ type diffusion layer 5, a reflection preventing film 6, a field film 7, an anode electrode 8, and a cathode electrode 9. On the other hand, a MOS transistor region 40 includes an N well diffusion layer 33, a P⁺ type diffusion layer 34, a gate oxidized film+polysilicon gate 35, a protective insulating film 36, and drain/source electrodes 37. Furthermore, a LOCOS (LOCal Oxidation of Silicon) is provided between the photodiode region and the MOS transistor.

The P-type semiconductor substrate 1 is such as a P-type silicon substrate. The P⁺ type embedded layer 2 is provided to cover the P-type semiconductor substrate 1. The P⁺ type embedded layer 2 is exemplified by a P-type silicon layer with high concentration of impurities. The P-type epitaxial layer 3 is provided to cover the P⁺ type embedded layer 2. The P-type epitaxial layer 3 is exemplified by a silicon layer having a high resistivity more than 100 Ωcm with a low concentration of impurities. The P⁺ type diffusion layer 4 is provided to penetrate from a surface of the P-type epitaxial layer 3 to a surface of the P⁺ type embedded layer 2 on a predetermined position outside a light receiving region. An impurities concentration of the P-type epitaxial layer 3 is lower than those of the P⁺ type embedded layer 2 and the P⁺ type diffusion layer 4. The P-type epitaxial layer 3 is exemplified by a P-type silicon layer with a high concentration of impurities. The N⁺ type diffusion layer 5 is shallowly embedded in a surface of the P-type epitaxial layer 3 on a predetermined position outside the light receiving region. The N⁺ type diffusion layer 5 is exemplified by an N-type silicon layer with a high concentration of impurities. The reflection preventing film 6 is provided to cover a surface (a surface of a channel region 30) of the P-type epitaxial layer 3 in the light receiving region. The reflection preventing film 6 includes an oxide film 6b such as a silicon oxide film and a nitride film 6a such as a silicon nitride film. Thicknesses of the films are set to prevent reflection of light in accordance with wavelengths of received lights. The field film 7 is provided to cover a surface of the P-type epitaxial layer 3 other than the light receiving region. The field film 7 includes an oxide film 7b such as a silicon oxide film and a nitride film 7a such as a silicon nitride film. The anode electrode 8 is provided to fill an opening of the field film 7 on the P⁺ type diffusion layer 4 and to reach the P⁺ type diffusion layer 4. The cathode electrode 9 is provided to fill an opening of the field film 7 on the N⁺ type diffusion layer 5 and to reach the N+type diffusion layer 5.

The N-type well diffusion layer 33 is provided in the P-type semiconductor substrate 1. The P⁺ type diffusion layers 34 are provided in the N-type well diffusion layer 33. The gate oxide film+polysilicon gate 35 is provided on the P-type semiconductor substrate 1 and is embedded with the protective insulating film 36. The drain/source electrodes 37 are provided to fill openings on the P⁺ type diffusion layers 34 and to reach the P⁺ type diffusion layer 34. The LOCOS 32 is formed of silicon oxide to insulate between the photodiode region 20 and the MOS transistor and between the MOS transistors.

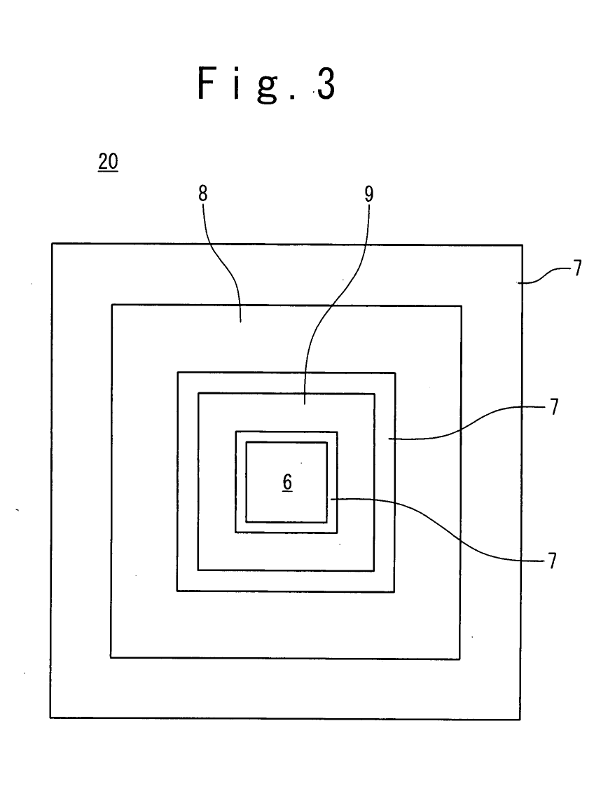

FIG. 3 is a plan view showing the photodiode region 20 in the configuration of the optical semiconductor device according to the embodiment of the present invention. In the photodiode region 20, the cathode electrode 9 and the anode electrode 8 are provided to surround the light receiving region provided with the reflection preventing film 6. Insulation among the surface of the P-type epitaxial layer 3, the cathode electrode 9, and the anode electrode 8 is accomplished with the field film 7.

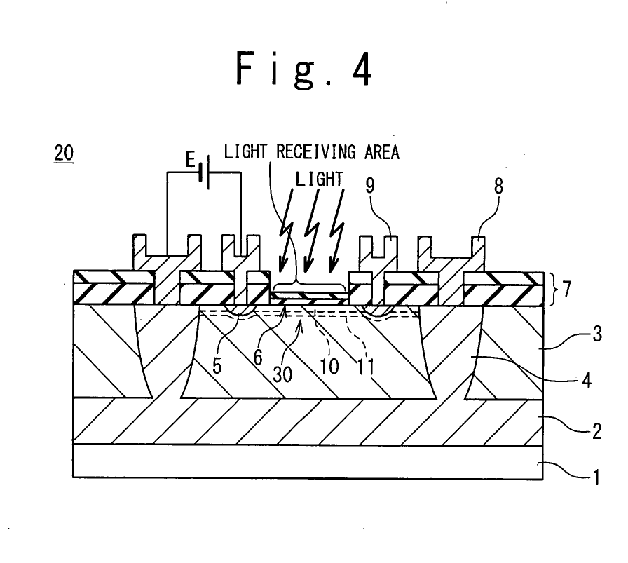

An operation of the optical semiconductor device according to the embodiment of the present invention will be described. FIG. 4 is a cross sectional view showing an operation principle of the optical semiconductor device in the embodiment of the present invention. In the present embodiment, a diffusion layer is not formed in a light receiving region, and a very shallow inversion layer 10 is formed by applying a bias of a reverse polarity between the anode electrode 8 and the cathode electrode 9 just under the field film 7 and the reflection preventing film 6, and the inversion layer is used as a cathode diffusion layer. More detailed description will be made below.

A silicon film with a high resistivity (more than 100 Ωcm) is used for the P-type epitaxial layer 3, and the reverse bias E over a predetermined voltage is applied between the anode electrode 8 and the cathode electrode 9. As a result, a very shallow inversion layer (N⁺ channel) 10 is formed on a surface (channel region 30) of the P-type epitaxial layer 3 just under the field film 7 composed of the oxide film 7b and the nitride film 7a and the reflection preventing film 6 composed of the oxide film 6b and the nitride film 6a. The very shallow inversion layer 10 functions as a cathode diffusion layer. That is to say, since photo carriers are generated inside the inversion layer 10 upon reception of light and the generated photo carriers are moved into a depletion layer 11 by an internal electric field produced on the basis of concentration gradient, a photoelectric current flows between the P⁺ type embedded layer 2 and P⁺ type diffusion layer 4 and the inversion layer (N⁺ channel) 10 through the p-n junction. At this time, the depletion layer 11 is extended to a side of a high resistivity layer when the reverse bias is applied. Therefore, a capacity of the photodiode (the P⁺ type embedded layer 2 and P⁺ type diffusion layer 4 and the inversion layer (N⁺ channel) 10) is reduced so that a high speed response is made possible at the same time.

It is known that charges of “+” are likely to present in the oxide films (SiO₂) 7b and 6b of the field film 7 and the reflection preventing film 6. For this reason, there is a case that holes are lack on the surface of the P-type epitaxial layer 3 in the vicinity of boundary between the P-type epitaxial layer 3 and the oxide films 7b and 6b because the holes are pushed by “+” charge in the oxide films 7b and 6b. Consequently, a layer in whose hole concentration is quite low is formed along the boundary. In such a situation, when the reverse bias E is applied between the anode electrode 8 and the cathode electrode 9, a P⁻ region of the P-type epitaxial layer 3 in the vicinity of the boundary becomes a depletion layer because of the+voltage applied via the oxide films 7b and 6b. Furthermore, when a high-intensity reverse bias is applied, the N-type inversion layer 10 appears by electrons gathering in the boundary. Thus, a p-n junction is realized between the P⁺ type embedded layer 2 and P⁺ type diffusion layer 4 and the inversion layer 10. When the inversion layer 10 is used as a cathode diffusion layer of a light receiving element, it is not required to form a cathode diffusion layer by a method such as ion-implantation. In addition, since the inversion layer 10 is very shallowly formed, reduction of quantum efficiency due to recombination on the surface of the P-type epitaxial layer 3 can be prevented so that the light receiving element of high sensitivity can be produced. As a result, it is not required to form a very shallow diffusion layer in the light receiving region. Since a diffusion layer is not formed, influence of heat treatment at high temperature in forming components other than the light receiving section can be prevented.

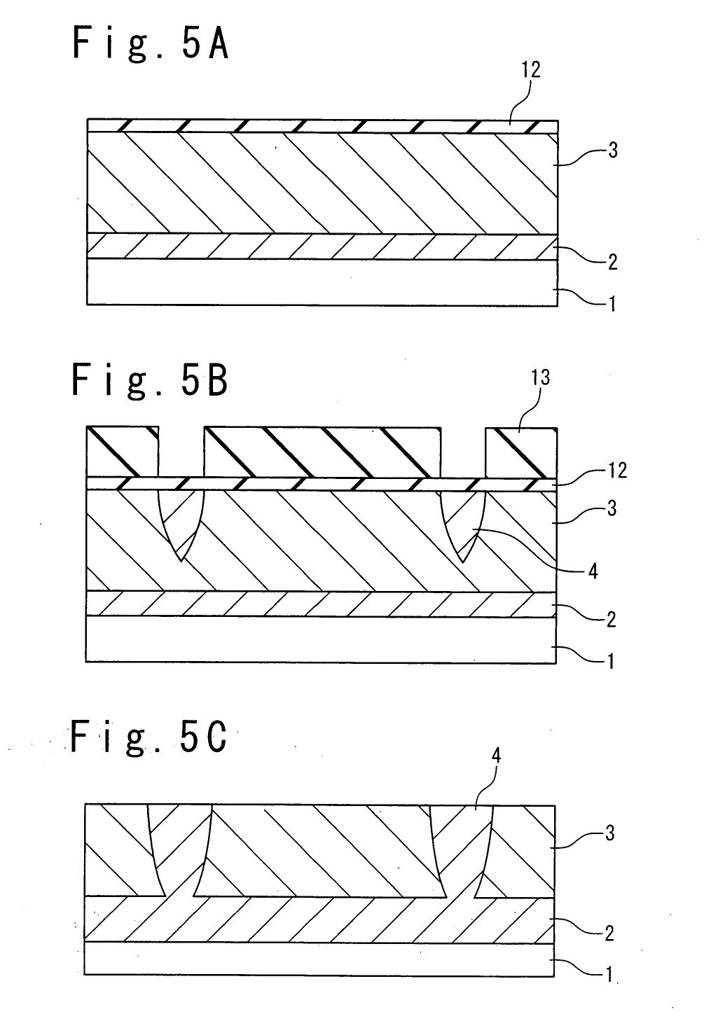

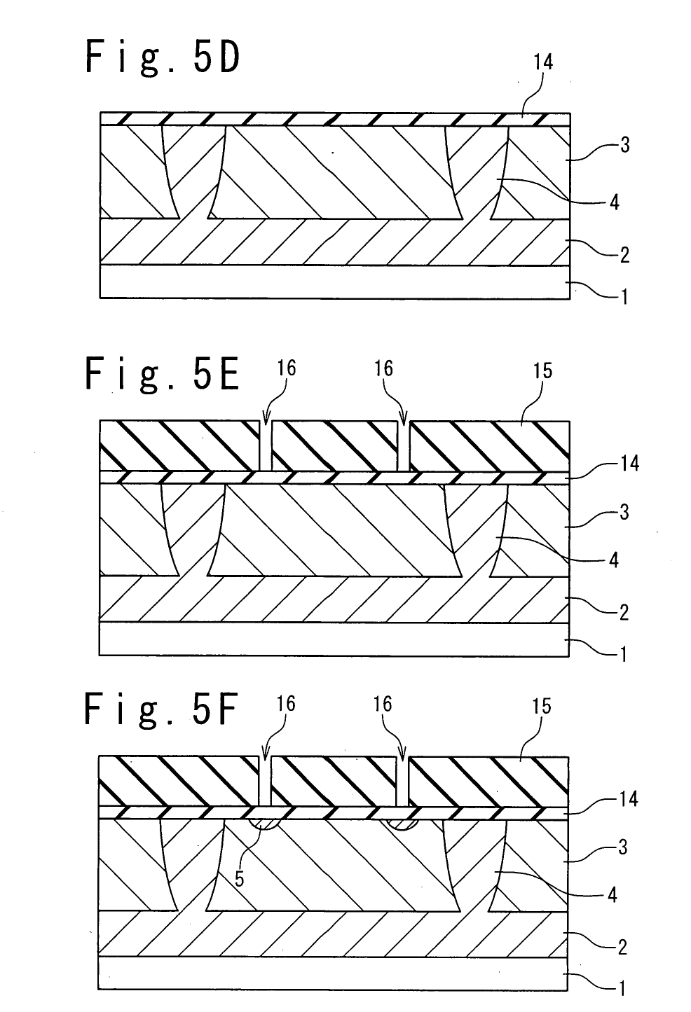

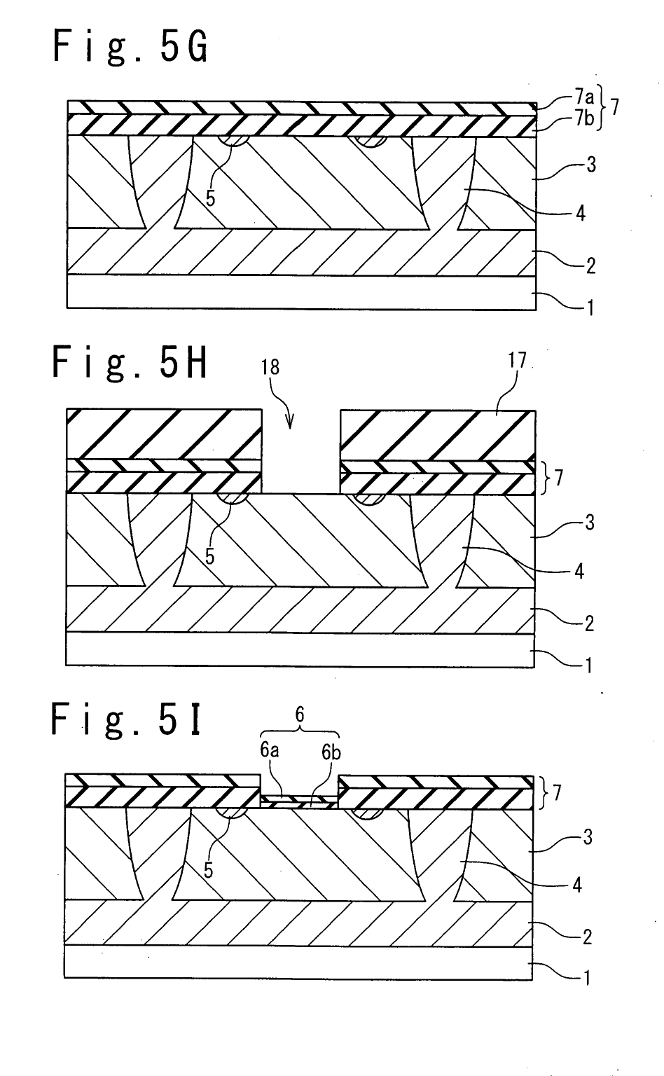

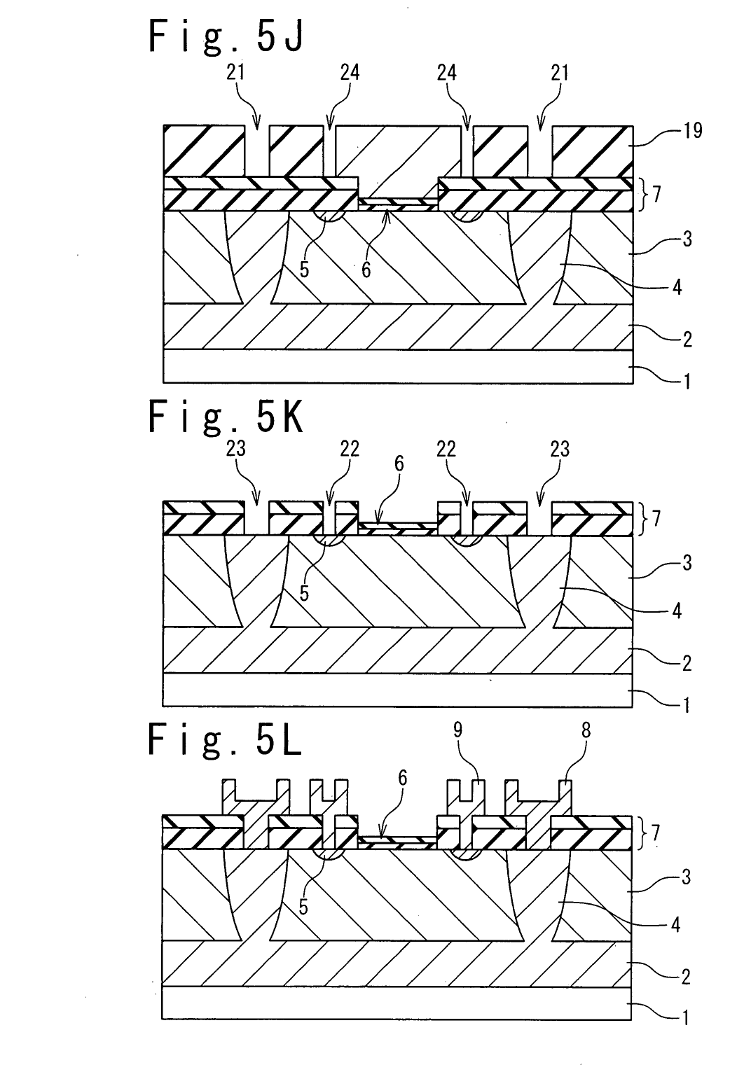

FIGS. 5A to 5L are cross sectional views showing a manufacturing method of the optical semiconductor device in the embodiment of the present invention. Referring to FIG. 5A, the P-type semiconductor substrate 1 of p type silicon whose resistivity is approximately 30 Ωcm (concentration of impurities: 4.44×10¹⁴ cm³) is prepared first. And then, the P⁺ type embedded layer 2 is formed by an impurity diffusion method to cover the P-type semiconductor substrate 1. A sheet resistance of the P⁺ type embedded layer 2 is approximately 100 Ω/□. After that, the P-type epitaxial layer 3 is formed by an epitaxial growth method to cover the P+type embedded layer 2. At this moment, a resistivity of the P-type epitaxial layer 3 is 100 Ωcm or more (concentration of impurities: less than 1.33×10¹⁴ cm⁻³). After that, an oxide film 12 of silicon oxide is formed through thermal oxidation on the surface of the P-type epitaxial layer 3.

Referring to FIG. 5B, a photoresist layer 13 is formed to cover the oxide film 12, and a patterning is carried out to the photoresist 13 through a lithography process. The P⁺ type diffusion layer 4 is formed to extend from a surface of the P-type epitaxial layer 3 toward the P-type semiconductor substrate 1 in openings of the photoresist 13 by the ion-implantation method or the impurity diffusion method. At this time, a concentration of impurities of the P⁺ type diffusion layer 4 is approximately 2.0×10¹⁹ cm⁻³.

Referring to FIG. 5C, after removing the photoresist 13 and the oxide film 12, p type impurities of the P⁺ type diffusion layer 4 and p type impurities of the P⁺ type embedded layer 2 mutually diffuse and are activated through a heat treatment process. As a result, the P⁺ type diffusion layer 4 and the P⁺ type embedded layer 2 are connected.

Referring to FIG. 5D, an oxide film 14 of silicon oxide is formed by thermally oxidizing the surface of the P-type epitaxial layer 3 and the P⁺ type diffusion layer 4. Referring to FIG. 5E, a photoresist layer 15 is formed to cover the oxide film 14, and a patterning is carried out to the photoresist 15 through the lithography process. Through this process, openings 16 are formed in the photoresist 15. With referring to FIG. 5F, the N⁺ type diffusion layers 5 are formed in a surface region of the P-type epitaxial layer 3 in the openings 16 of the photoresist 15 by the ion-implantation method or the impurity diffusion method. At this time, a concentration of impurities of the N⁺ type diffusion layer 5 is approximately 2.0×10¹⁹ cm⁻³.

Referring to FIG. 5G, subsequently, after removing the photoresist 15 and the oxide film 14, n type impurities in the N⁺ type diffusion layer 5 diffuse and are activated through a heat treatment process. After that, the oxide film 7b of silicon oxide is formed by thermally oxidizing the surfaces of the P-type epitaxial layer 3 and the P⁺ type diffusion layers 4. At this time, a film thickness of the oxide film 7b is approximately 50 nm. The oxidization is carried out in an ISSG (In Situ Steam Generation) method of atmosphere at 1050° C. and in 5% H₂. Subsequently, the nitride film 7a of silicon nitride is formed through a CVD method to cover the oxide film 7b. At this time, a film thickness of the nitriding film 7a is approximately 180 nm.

Referring to FIG. 5H a photoresist layer 17 is formed to cover the nitriding film 7a, and a patterning is carried out to the photoresist layer 17 through the lithography process. The nitride film 7a and the oxide film 7b are removed in an opening 18 of the photoresist layer 17 by using a dry etching. As a result, in the opening 18, the surface of the P-type epitaxial layer 3 is exposed. The exposed region is a light receiving region. In addition, the field film 7 is formed as a laminated film of the oxide film 7b and the nitride film 7a.

Referring to FIG. 5I, after that, the oxide film 6b of silicon oxide is formed by the CVD method to cover the exposed region of the P-type epitaxial layer 3. At this time, a film thickness of the oxide film 6b is approximately 10 nm. Subsequently, the nitride film 6a of silicon nitride is formed by the CVD method to cover the oxide film 6b. At this time, a film thickness of the nitride film 7a is approximately 40 nm. After that, by removing the photoresist 17, the oxide film 6b and the nitride film 6a on the photoresist layer 17 are also removed. As a result, the reflection preventing film 6 as the laminated film of the oxide film 6b and the nitride film 6a is formed in the light receiving region. Film thicknesses of the oxide film 6b and the nitriding film 6a are preliminarily determined on the basis of a wavelength of light to be received.

Referring to FIG. 5J, a photoresist layer 19 is formed to cover the field film 7 and the reflection preventing film 6, and a patterning is carried out to the photoresist 19 through the lithography process. Thus, openings 24 and 21 are formed in the photoresist layer 19. Referring to FIG. 5K, subsequently, in the openings 24 and 21 of the photoresist layer 19, through-holes 22 and 23 are formed in the field film 7 by the dry etching. At this time, the through-hole 22 is formed on the N⁺ type diffusion layer 5 so that the N⁺ type diffusion layers 5 can be exposed. The through-hole 23 is formed on the P⁺ type diffusion layer 4 so that the P⁺ type diffusion layers 4 can be exposed. Referring to FIG. 5L, after that, through the lithography process, the metal film formation process, and the photoresist removing process, the cathode electrode 9 is provided to fill the opening part 22 and to reach a surface of the N⁺ type diffusion layer 5, and the anode electrode 8 is provided to fill the opening part 23 and to reach the surface of the P⁺ type diffusion layer 4.

Through the processes described above, the photodiode region 20 is manufactured.

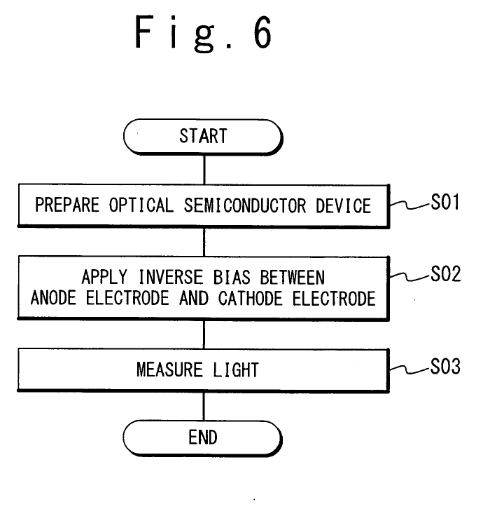

An operation method of the optical semiconductor device of the present invention will be described. FIG. 6 is a flowchart showing an operation of the optical semiconductor device in the embodiment of the present invention. At first, the optical semiconductor device (FIG. 2) is prepared (step S01). Then, by applying the reverse bias E between the anode electrode 8 and the cathode electrode 9, the optical semiconductor device (FIG. 4) is set to a state ready to measure (step S02). Thus, the very shallow inversion layer (N⁺ channel) 10 is formed on the surface of the P-type epitaxial layer 3 just under the field film 7 and the reflection preventing film 6. The very shallow inversion layer 10 operates as a cathode diffusion layer. By radiating light to be measured, the optical semiconductor device (FIG. 4) receives the light (step S03). When the light reaches the surface of the P-type epitaxial layer 3, photo carriers are generated inside the inversion layer 10 because of receiving of the light, and photoelectric current flows through the p-n junction between the P⁺ type embedded layer 2 and P⁺ type diffusion layer 4 and the inversion layer (N⁺ channel) 10 since the photocarriers are moved into the depletion layer 11 by an internal electric field generated on the basis of concentration gradient. The measurement is performed in a manner that the photoelectric current is taken from the anode electrode 8 via the P⁺ type embedded layer 2 and P⁺ type diffusion layer 4 and is measured.

In the present invention, the very shallow inversion layer (N⁺ channel) 10 is formed under the field film and the reflection preventing film by using silicon with a high resistance for the P-type epitaxial layer 3 and by applying the reverse bias E between the anode electrode 8 and the cathode electrode 9. The formed N⁺ channel (the inversion layer 10) operates as a light receiving region through the p-n junction with P-type diffusion layers (P⁺ type embedded layer 2 and P⁺ type diffusion layer 4). Thus, even when an invasive length of incidence light of short wavelength in the semiconductor is short, photo carriers are converted into a photo electric current with high efficiency since the formed very shallow N⁺ channel operates as a cathode diffusion layer to prevent lowering of quantum efficiency through recombination of the photocarriers.

According to the present invention, light of short wavelength such as blue laser can be received with a high sensitivity and high speed response. In addition, a light receiving element that is able to receive light of short wavelength such as a blue laser with the high sensitivity and high-speed response can be manufactured in a simple way and low cost process.

Although the present invention has been described above in connection with several embodiments thereof, it will be apparent to those skilled in the art that those embodiments are provided solely for illustrating the invention, and should not be relied upon to construe the appended claims in a limiting sense.

What is claimed is:

1. An optical semiconductor device comprising a photodiode, comprising:
a first semiconductor layer of a first conductive type; and
a channel layer of a second conductive type formed from a surface portion of said first semiconductor layer in a light receiving region,
wherein said channel layer and said first semiconductor layer in said light receiving region, form a p-n junction region.

2. The optical semiconductor device according to claim 1, further comprising:
a second semiconductor layer of said second conductive type; and
a light transmissible insulating film formed on said first semiconductor layer in said light receiving region,
wherein said channel layer is formed in a surface region of said first semiconductor layer under said light transmissible insulating film when a reverse bias is applied between said first and second semiconductor layers.

3. The optical semiconductor device according to claim 2, wherein said second semiconductor layer is formed to surround said light receiving region.

4. The optical semiconductor device according to claim 2, further comprising:
a third semiconductor layer of said first conductive type formed outside of said second semiconductor layer to surround said second semiconductor layer.

5. The optical semiconductor device according to claim 2, wherein said first conductive type is a P-type, and said second conductive type is an N-type.

6. The optical semiconductor device according to claim 2, wherein said insulating film is a silicon oxide film.

7. The optical semiconductor device according to claim 2, wherein a resistivity of said first semiconductor layer is 100 Ωcm or more.

8. The optical semiconductor device according to claim 2, further comprising:
a fourth semiconductor layer of said first conductive type formed under said first semiconductor layer, and connected to said third semiconductor layer.

9. The optical semiconductor device according to claim 8, wherein an impurity concentration of said first semiconductor layer is lower than those of said third and fourth semiconductor layers.

10. The optical semiconductor device according to claim 2, further comprising:
a transistor formed on a semiconductor substrate on or above which said photodiode is formed.

11. An operation method of an optical semiconductor device, comprising:
providing said optical semiconductor device, which comprises:
a first semiconductor layer of a first conductive type;
a second semiconductor layer of a second conductive type formed in a surface portion on said semiconductor layer;
a third semiconductor layer of the first conductive type formed under said first semiconductor layer;
a fourth semiconductor layer of the first conductive type formed to pass through said first semiconductor layer to said third semiconductor layer;
a first electrode provided on said second semiconductor layer; and
a second electrode provided on said fourth semiconductor layer, applying a reverse bias voltage between said first semiconductor layer and said second semiconductor layer to form a channel layer of the second conductive type in a surface portion of said first semiconductor layer; and
detecting a photoelectric current generated when a light is inputted in a light receiving region, in which a pn junction region is formed.

12. The operation method according to claim 11, wherein said detecting comprises:
detecting the photoelectric current generated when the blue light is inputted in said light receiving region.
